(19) United States
(12) Patent Application Publication
(10) Pub. No.: US 2026/0255491 A1
(43) Pub. Date: Aug. 27, 2026

(54) WIRING BOARD AND METHOD OF MANUFACTURING WIRING BOARD

(71) Applicant: SHINKO ELECTRIC INDUSTRIES CO., LTD., Nagano-shi (JP)

(72) Inventor: Tomoya Kitamura, Nagano (JP)

(21) Appl. No.: 19/545,816

(22) Filed: Feb. 20, 2026

(30) Foreign Application Priority Data
Feb. 27, 2025 (JP) 2025-029763

(51) Int. Cl. H05K 1/181; H05K 3/341

(52) U.S. Cl. CPC H05K 1/181; H05K 3/3436; H05K 2201/10234; H05K 2201/10734

(57) ABSTRACT

A wiring board includes a connecting terminal that is formed on an upper surface of an insulating layer. The connecting terminal includes a seed layer, a post of a metal, a protective metal layer, a solder layer, and an alloy layer. The seed layer is layered on the upper surface of the insulating layer. The post is layered on an upper surface of the seed layer. The protective metal layer is layered on an upper surface of the post. The solder layer is formed on an upper surface of the protective metal layer. The alloy layer is formed in an interface between the protective metal layer and the solder layer. The solder layer covers an upper surface and a side surface of the alloy layer. The side surface of the alloy layer is positioned on a center side of the post with respect to a side surface of the post.

### CROSS-REFERENCE TO RELATED APPLICATION

This application is based upon and claims the benefit of priority of the prior Japanese Patent Application No. 2025-029763, filed on February 27, 2025, the entire contents of which are incorporated herein by reference.

### FIELD

The embodiment discussed herein is related to a wiring board and a method of manufacturing a wiring board.

### BACKGROUND

In general, on a wiring board on which a semiconductor chip is to be mounted, connecting terminals for connection with the semiconductor chip are formed in some cases. The connecting terminals are protrusions of metal that are formed on a surface of the wiring board. For such connecting terminals, for example, a multi-layered structure obtained by layering a plurality of metal layers is employed in some cases.

Specifically, a seed layer of, for example, metal such as copper is formed on a surface of an insulating layer forming a wiring board, a post made of, for example, metal such as copper is formed on an upper surface of the seed layer, and a protective metal layer made of, for example, metal such as nickel is formed on an upper surface of the post. After a solder layer is layered on an upper surface of the protective metal layer, connecting terminals whose surface are hemispherical are formed by fusing only the solder layer by a reflow soldering process.

Patent Literature 1: Japanese Laid-open Patent Publication No. 2022-189275

In the above-described wiring board having the connecting terminals has a problem in that short-circuiting occurs between adjacent connecting terminals. Specifically, when the reflow soldering process is performed on the solder layer that is the top of the connecting terminals, the solder layer is fused and extends horizontally and accordingly the solder layers of adjacent connecting terminals make contact with each other and this sometimes results in occurrence of short-circuiting between the adjacent connecting terminals.

### SUMMARY

According to an aspect of an embodiment, a wiring board includes an insulating layer; and a connecting terminal that is formed on an upper surface of the insulating layer, wherein the connecting terminal includes a seed layer that is layered on the upper surface of the insulating layer; a post of a metal that is layered on an upper surface of the seed layer; a protective metal layer that is layered on an upper surface of the post; a solder layer that is formed on an upper surface of the protective metal layer; and an alloy layer that is formed in an interface between the protective metal layer and the solder layer and that is at least partly made of an intermetallic compound, the solder layer covers an upper surface and a side surface of the alloy layer, and the side surface of the alloy layer is positioned on a center side of the post with respect to a side surface of the post.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to an embodiment;

FIG. 2 is a diagram illustrating a connecting terminal according to the embodiment in an enlarged manner;

FIG. 3 is a flowchart illustrating a method of manufacturing a semiconductor device according to the embodiment;

FIG. 4 is a diagram illustrating a specific example of a core substrate forming step;

FIG. 5 is a diagram illustrating a specific example of a build-up step;

FIG. 6 is a diagram illustrating a specific example of a solder resist layer forming step;

FIG. 7 is a diagram illustrating a specific example of a connecting terminal forming step;

FIG. 8 is a diagram illustrating a specific example of a semiconductor chip mounting step;

FIG. 9 is a flowchart illustrating the connecting terminal forming step according to the embodiment;

FIG. 10 is a diagram illustrating an opening of the solder resist layer;

FIG. 11 is a diagram illustrating formation of a seed layer;

FIG. 12 is a diagram illustrating patterning;

FIG. 13 is a diagram illustrating formation of a post;

FIG. 14 is a diagram illustrating formation of a protective metal layer;

FIG. 15 is a diagram illustrating formation of a metal layer;

FIG. 16 is a diagram illustrating formation of a solder layer;

FIG. 17 is a diagram illustrating removal of a resist;

FIG. 18 is a diagram illustrating seed layer etching;

FIG. 19 is a diagram illustrating reflow soldering;

FIG. 20 is a diagram illustrating a structure of a connecting terminal according to Modification 1 of the embodiment;

FIG. 21 is a diagram illustrating a structure of a connecting terminal according to Modification 2 of the embodiment;

FIG. 22 is a diagram illustrating a structure of a connecting terminal according to Modification 3 of the embodiment;

FIG. 23 is a diagram illustrating formation of a post;

FIG. 24 is a diagram illustrating formation of a protective metal layer;

FIG. 25 is a diagram illustrating formation of a metal layer; and

FIG. 26 is a diagram illustrating formation of a solder layer.

### DESCRIPTION OF EMBODIMENT

An embodiment of a wiring board and a method of manufacturing a wiring board disclosed herein will be

described in detail below based on the accompanying drawings. Note that the embodiment does not limit the disclosed technique.

### Embodiment

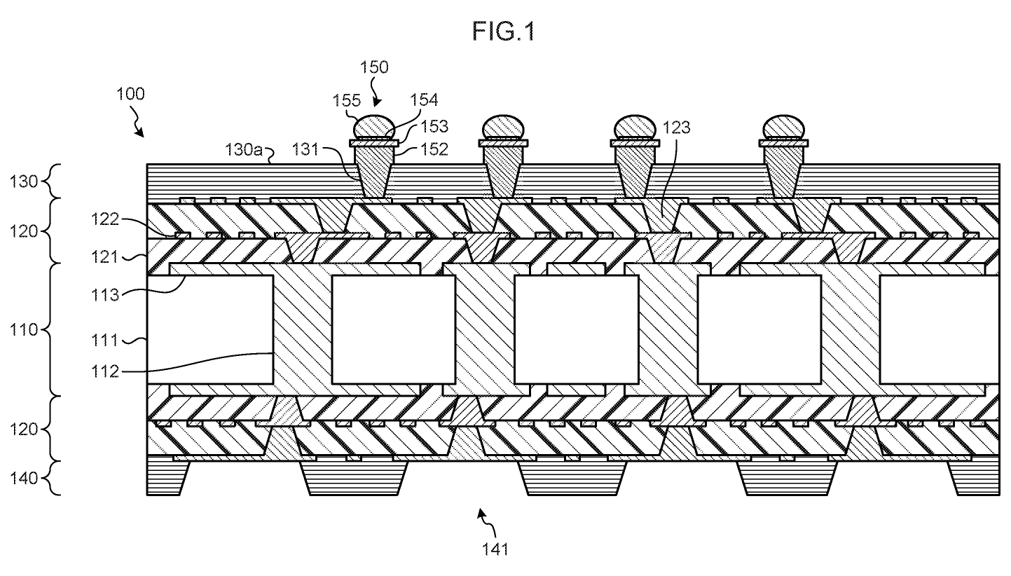

FIG. 1 is a diagram illustrating a configuration of a wiring board 100 according to the embodiment. FIG. 1 schematically illustrates a cross-section of the wiring board 100. The wiring board 100 illustrated in FIG. 1, for example, is usable as a board of a semiconductor device on which a semiconductor chip is mounted.

The wiring board 100 is a layered structure and includes a core substrate 110, a multi-layered interconnect structure 120, and solder resist layers 130 and 140. It is described below that, as illustrated in FIG. 1, the solder resist layer 140 is the bottom layer and the solder resist layer 130 is the top layer; however, the wiring board 100 may be used upside down and may be used in any posture.

The core substrate 110 is obtained by forming an interconnect layer 113 by metal plating on both surfaces of a substrate 111 that is a platy insulator. The interconnect layers 113 on both surfaces are connected via through interconnects 112 penetrating the substrate 111 as required.

The multi-layered interconnect structure 120 is obtained by layering a layer including an insulating layer 121 that is insulative and an interconnect layer 122 that is conductive. The insulating layer 121 is formed using an insulative resin such as epoxy resin or polyimide resin. The interconnect layer 122 is formed using, for example, metal such as copper or a copper alloy. In FIG. 1, two layers are formed in the multi-layered interconnect structure 120 above the core substrate 110 and two layers are layered in the multi-layered interconnect structure 120 below the core substrate 110, and the number of layers that are layered may be one or three or more. The interconnect layers 113 and 122 that are adjacent to each other via the insulating layer 121 are connected with a via 123 penetrating the insulating layer 121 as required.

The solder resist layer 130 is a layer that covers the interconnect layer 122 on a surface of the multi-layered interconnect structure 120 and that protects interconnects. The solder resist layer 130 is a layer that is made of, for example, an insulative photosensitive resin such as acrylic resin or polyimide resin and is one of insulating layers. Note that the solder resist layer 130 may be formed using, for example, an insulating non-photosensitive resin such as epoxy resin.

On the side of the solder resist layer 130, the wiring board 100 has a surface on which electric parts such as a semiconductor chip are formed. Openings 131 are formed in the solder resist layer 130 in a position where a semiconductor chip is mounted. In other words, the openings 131 are formed in the solder resist layer 130 in order to connect electrodes of the semiconductor chip and the interconnect layer 122 of the multi-layered interconnect structure 120 to each other. When the solder resist layer 130 is formed using photosensitive resin, it is possible to form the openings 131 by exposure and development. When the solder resist layer 130 is formed using non-photosensitive resin, it is possible to form the openings 131 by laser processing. In the opening 131, a connecting terminal 150 that connects the interconnect layer 122 of the multi-layered interconnect structure 120 and the electrode of the semiconductor chip is formed. The connecting terminal 150 is a protrusion electrode that is formed such that the protrusion electrode protrudes from an upper surface 130a of the solder resist layer 130.

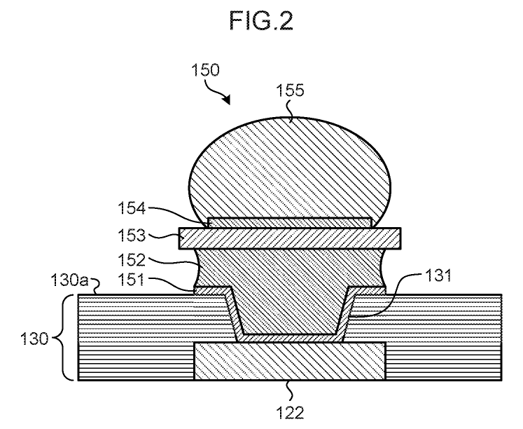

A structure of the connecting terminal 150 will be described here with reference to FIG. 2. FIG. 2 is a diagram illustrating the connecting terminal 150 according to the embodiment in an enlarged manner.

As illustrated in FIG. 2, the connecting terminal 150 is a multi-layered structure obtained by layering a plurality of metal layers. Specifically, the connecting terminal 150 has a seed layer 151, a post 152, a protective metal layer 153, an alloy layer 154, and a solder layer 155.

The seed layer 151 is a metal layer that is formed on an inner surface and the upper surface 130a of the solder resist layer 130 and an upper surface of the interconnect layer 122 exposed to a bottom part of the opening 131. The seed layer 151 is provided in an annular shape on the upper surface 130a of the solder resist layer 130 on a periphery of the opening 131. The seed layer 151 is made of, for example, copper (Cu) and is layered by electroless plating on the inner surface and the upper surface 130a of the opening 131 of the solder resist layer 130. The seed layer 151 can have a thickness of approximately 10 nm to 500 nm.

The post 152 is an electrode that is a main part of the connecting terminal 150 and is formed on an upper surface of the seed layer 151 by, for example, copper (Cu) electrolytic plating. The post 152 can be formed by, for example, a semi-additive process. The post 152 can have a thickness (in other words, a thickness of only a part above the upper surface of the seed layer 151 excluding the part in the opening 131) of, for example, approximately 2 μm to 50 μm.

The protective metal layer 153 is a metal layer that is formed on an upper surface of the post 152. The protective metal layer 153 is made of, for example, nickel (Ni) and is layered on the upper surface of the post 152 by electrolytic plating. The protective metal layer 153 can have a thickness of, for example, approximately 0.01 μm to 3 μm.

The solder layer 155 is a metal layer formed on an upper surface of the protective metal layer 153. The solder layer 155 is made of, for example, tin (Sn) and is layered by electrolytic plating on the upper surface of the protective metal layer 153. The solder layer 155 may be formed using, except for tin (Sn), various types of solder metal such as a tin-silver (Sn-Ag) alloy, a tin-silver-copper (Sn-Ag-Cu) alloy, and a tin-bismuth (Sn-Bi) alloy. An upper surface of the solder layer 155 protrudes to an upper side in a form of a curved surface (for example, spherically). The solder layer 155 is, for example, hemisphere. The solder layer 155 that is hemisphere is obtained by performing reflow soldering on the solder layer 155 formed on the upper surface of the protective metal layer 153 by electrolytic plating. The solder layer 155 that is hemisphere is also referred to as "solder bump".

The alloy layer 154 is formed in an interface (that is, bonding surface) between the protective metal layer 153 and the solder layer 155. A layer of metal (e.g., copper (Cu)) formed on the upper surface of the protective metal layer 153 and different from the protective metal layer 153 and the solder layer 155 react and accordingly the alloy layer 154 is formed. The alloy layer 154 is a layer formed of an intermetallic compound containing at least a metal (e.g., copper (Cu)) different from the protective metal layer 153 and tin (Sn) forming the solder layer 155. The intermetallic compound forming the alloy layer 154 may contain a metal (e.g., copper (Cu)) different from that of the protective metal layer 153, tin (Sn) forming the solder layer 155, and nickel (Ni) forming the protective metal layer 153. The intermetallic compound forming the alloy layer 154 is, for example, (Cu,Ni)₆Sn₅.

As illustrated in FIG. 2, the solder layer 155 covers an upper surface and a side surface of the alloy layer 154. The side surface of the alloy layer 154 covered with the solder layer 155 is positioned on a center side of the post 152 with respect to a side surface of the post 152. In other words, the side surface of the alloy layer 154 is positioned backward to the center side of the post 152 with respect to the side surface of the post 152. The side surface of the post 152 refers to a side surface of only a part above the upper surface of the seed layer 151 excluding the part in the opening 131. The side surface of the alloy layer 154 is positioned on the center side of the post 152 with respect to the side surface of the post 152 and therefore the side surface of the alloy layer 154 and a side surface of the protective metal layer 153 form a step receding to the center side of the post 152 near the side surface of the alloy layer 154.

As described above, in the embodiment, because the side surface of the alloy layer 154 is positioned on the center side of the post 152 with respect to the side surface of the post 152, it is possible to inhibit the solder layer 155 covering the side surface of the alloy layer 154 from extending in the lateral direction from the side surface of the alloy layer 154. In other words, when the side surface of the alloy layer 154 is positioned on an outer side with respect to the side surface of the post 152, a step between the side surface of the alloy layer 154 and the side surface of the protective metal layer 153 is relatively small and the solder layer 155 can extend easily from the side surface of the alloy layer 154 in the lateral direction. On the other hand, when the side surface of the alloy layer 154 is positioned on the center side of the post 152 with respect to the side surface of the post 152 is, the step between the side surface of the alloy layer 154 and the side surface of the protective metal layer 153 is relatively large. This makes it possible to inhibit the solder layer 155 from extending from the side surface of the alloy layer 154 in the lateral direction and thus it is possible to inhibit the solder layers 155 of the connecting terminals 150 adjacent to each other from making contact with each other. As a result, it is possible to inhibit occurrence of short-circuiting between the connecting terminals 150 adjacent to each other.

In the embodiment, the alloy layer 154 has a width smaller than that of the post 152. This makes it possible to recede the side surface of the alloy layer 154 to the center side of the post 152 with respect to the side surface of the post 152 and inhibits extension of the solder layer 155 in the horizontal direction.

In the embodiment, the alloy layer 154 is a layer made of the intermetallic compound containing at least the medal (e.g., copper (Cu)) different from that of the protective metal layer 153 and tin (Sn) forming the solder layer 155. The alloy layer 154 is formed of the intermetallic compound containing at least Cu and Sn and therefore it is possible to inhibit Sn in the solder layer 155 from diffusing to Ni in the protective metal layer 153 and thus inhibit a progress of reaction of Ni of the protective metal layer 153. As a result, it is possible to inhibit depletion of Ni in the protective metal layer 153 and inhibit the connecting terminal 150 from breaking in the position of the protective metal layer 153.

In the embodiment, the side surface of the protective metal layer 153 is positioned on an outer side with respect to the side surface of the post 152. The side surface of the alloy layer 154 is positioned on the center side of the post 152 with respect to the side surface of the protective metal layer 153. The solder layer 155 extends from the side surface of the alloy layer 154 in the direction along the upper surface of the protective metal layer 153 and exposes an area not overlapping the solder layer 155 in a plane view in the upper surface of the protective metal layer 153. The area not overlapping the solder layer 155 in the plane view in the upper surface of the protective metal layer 153 is provided in an annular shape around the solder layer 155. Exposing the area not overlapping the solder layer 155 in the plane view in the upper surface of the protective metal layer 153 makes it possible to increase visibility of the upper surface of the protective metal layer 153. As a result, it is possible to increase accuracy of examination using reflected light from the upper surface of the protective metal layer 153, and the like.

In the embodiment, the solder layer 155 has a width smaller than that of the protective metal layer 153. In other words, the width of the solder layer 155 in the direction along the upper surface of the protective metal layer 153 is smaller than the width of the protective metal layer 153 in the direction along the upper surface of the protective metal layer 153. This increases the area of exposure of the area not overlapping the solder layer 155 in the plane view in the upper surface of the protective metal layer 153 and thus it is possible to increase visibility of the upper surface of the protective metal layer 153. As a result, it is possible to increase accuracy of examination using reflected light from the upper surface of the protective metal layer 153, or the like. In this case, the solder layer 155 may have a width larger than that of the post 152. This makes it possible to ensure a volume of the solder layer 155 sufficient to join the electrodes of the semiconductor chip.

Back to description of FIG. 1. The solder resist layer 140 is a layer that covers the interconnect layer 122 on a surface of the multi-layered interconnect structure 120 as the solder resist layer 130 does and that protects interconnects. The solder resist layer 140 is a layer made of, for example, an insulative photosensitive resin such as acrylic resin or polyimide resin and is one of insulating layers. Note that the solder resist layer 140 may be formed using, for example, an insulating non-photosensitive resin such as epoxy resin.

On the side of the solder resist layer 140, the wiring board 100 has a face that is connected to an external part or an external device. An opening 141 is formed in the solder resist layer 140 in a position in which an external connecting terminal that is electrically connected to an external part or an external device is formed and the interconnect layer 122 of the multi-layered interconnect structure 120 is exposed from the opening 141. In the opening 141, for example, an external connecting terminal such as a solder ball is formed. When the solder resist layer 140 is formed using photosensitive resin, it is possible to form the opening 141 by exposure and development. When the solder resist layer 140 is formed using a non-photosensitive resin, it is possible to form the opening 141 by laser processing.

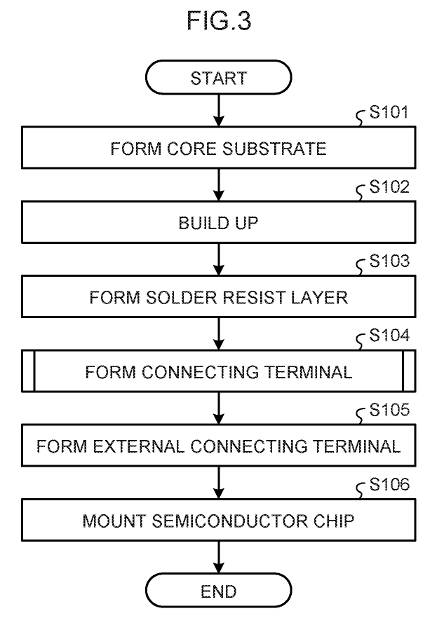

Taking a specific example, a method of manufacturing a semiconductor device including the wiring board 100 configured as described above will be described next with reference to FIG. 3. FIG. 3 is a flowchart illustrating the method of manufacturing a semiconductor device according to the embodiment.

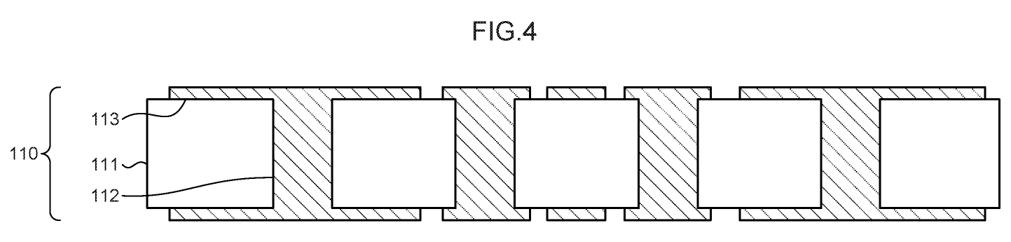

First of all, the core substrate 110 serving as a support member of the wiring board 100 is formed (step S101). Specifically, for example, as illustrated in FIG. 4, a penetrating interconnect 112 penetrating the substrate 111 that is a platy insulator is formed on the substrate 111 and the interconnect layer 113 of, for example, metal

such as copper or a copper alloy is formed using, for example, a copper foil or by copper plating on both surfaces of the substrate 111. FIG. 4 is a diagram illustrating a specific example of a core substrate forming step. The interconnect layers 113 on both surfaces of the substrate 111 are connected with the penetrating interconnect 112 formed by, for example, plating with a metal such as copper or a copper alloy as required. For example, what obtained by immersing a reinforcing member, such as glass woven fabric, in an insulating resin such as epoxy resin is usable as the substrate 111. A glass non-woven fabric, an aramid woven fabric or an aramid non-woven fabric is usable other than the glass fabric as the reinforcing material. A polyimide resin or a cyanate resin is usable other than epoxy resin as the insulative resin.

The multi-layered interconnect structure 120 is then formed by a build-up method on an upper surface and a lower surface of the core substrate 110 (step S102). Specifically, for example, as illustrated in FIG. 5, the insulating layer 121 is formed on the upper surface and the lower surface of the core substrate 110 and the interconnect layer 122 is formed on a surface of the insulating layer 121. FIG. 5 is a diagram illustrating a specific example of a build-up step. The insulating layer 121 is formed using, for example, an insulating resin such as epoxy resin or polyimide resin. The interconnect layer 122 is formed by, for example, plating with a metal such as copper or a copper alloy. For example, the interconnect layer 122 is formed by a semi-additive method.

The interconnect layer 113 of the core substrate 110 and the interconnect layer 122 or the adjacent interconnect layers 122 are connected with each other with, for example, the via 123 that is formed by plating with a metal such as copper or a copper alloy as required. A plurality of the insulating layers 121 and a plurality of the interconnect layers 122 may be formed on the upper surface and the lower surface of the core substrate 110.

After the multi-layered interconnect structure 120 is formed, the interconnect layer 122 on the surface of the multi-layered interconnect structure 120 is covered with the solder resist layers 130 and 140 (step S103). In other words, the interconnect layer 122 on the surface of the multi-layered interconnect structure 120 layered on the upper surface of the core substrate 110 is covered with the solder resist layer 130 and the interconnect layer 122 on the surface of the multi-layered interconnect structure 120 layered on the lower surface of the core substrate 110 is covered with the solder resist layer 140.

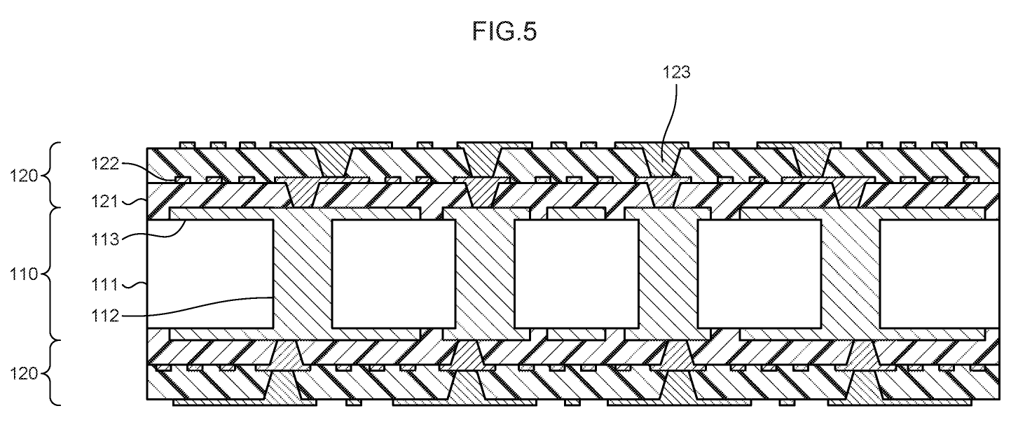

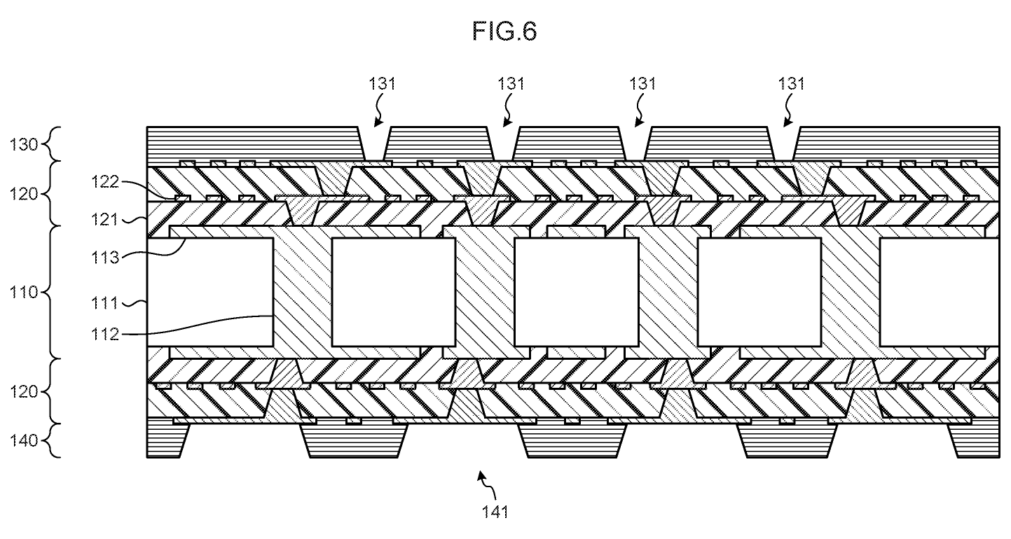

For example, as illustrated in FIG. 6, in the solder resist layer 130 on the side where the semiconductor chip is mounted, the openings 131 are formed in positions where the connecting terminals for connection with the semiconductor chip are provided. FIG. 6 is a diagram illustrating a specific example of a solder resist layer forming step. The interconnect layer 122 on the surface of the multi-layered interconnect structure 120 is exposed to the bottom of the opening 131. On the other hand, in the solder resist layer 140 on the side of connection to an external part or an external device, the opening 141 is formed in a position where the external connecting terminal is provided. The interconnect layer 122 on the surface of the multi-layered interconnect structure 120 is exposed to a bottom of the opening 141.

When a photosensitive resin is used as the solder resist layers 130 and 140, it is possible to form the openings 131 and 141 by exposure and development. When a non-photosensitive resin is used as the solder resist layers 130 and 140, it is possible to form the openings 131 and 141 by laser processing.

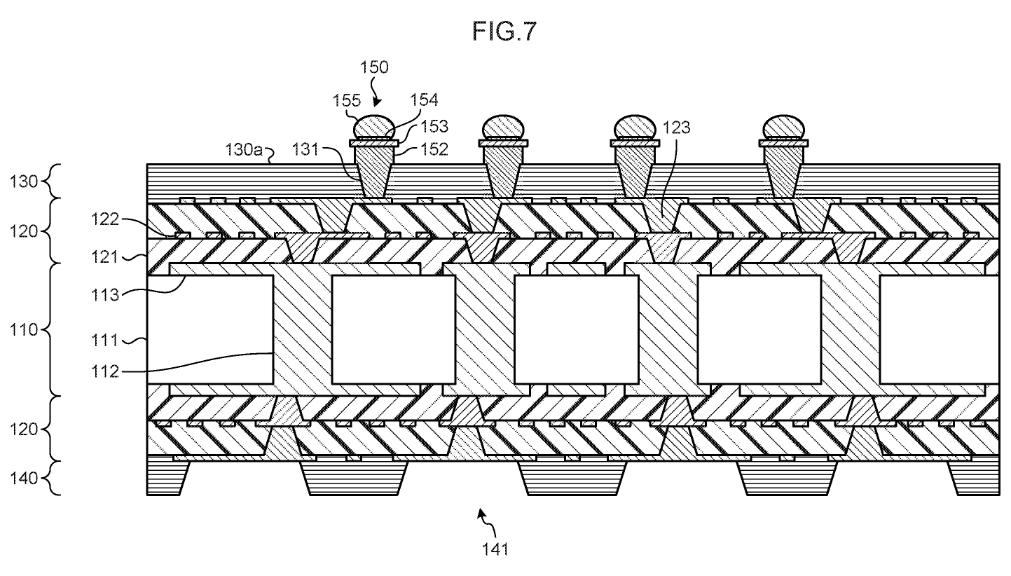

The connecting terminals for connecting the semiconductor chip are formed in the openings 131 of the solder resist layer 130 (step S104). In other words, for example, as illustrated in FIG. 7, the connecting terminals 150 are formed in the openings 131. FIG. 7 is a diagram illustrating a specific example of a connecting terminal forming step. The connecting terminal 150 is a multi-layered structure and includes the seed layer 151 (see FIG. 2), the post 152, the protective metal layer 153, the alloy layer 154, and the solder layer 155 and the solder layer 155 layered on the upper surface of the protective metal layer 153 protrudes to the upper side in the form of a curved surface (for example, spherically). All the seed layer 151, the post 152, the protective metal layer 153, and the solder layer 155 are formed by plating.

The seed layer 151 is formed by, for example, performing electroless plating with copper (Cu) on the inner surface and the upper surface 130a of the opening 131 of the solder resist layer 130. The post 152 is formed by performing, for example, electrolytic plating with copper (Cu) on the upper surface of the seed layer 151 in and around the opening 131. The protective metal layer 153 is formed by performing, for example, electrolytic plating with nickel (Ni) on the upper surface of the post 152.

Then, a copper (Cu) metal layer is formed by performing electrolytic plating with copper (Cu) on the upper surface of the protective metal layer 153 and the solder layer 155 is formed by performing, for example, electrolytic plating with tin (Sn) via the metal layer on the upper surface of the protective metal layer 153.

After the seed layer 151, the post 152, the protective metal layer 153, the metal layer, and the solder layer 155 are formed sequentially, an unnecessary part of the seed layer 151 is removed by etching. When the seed layer 151 is removed, the post 152 and the metal layer are thinned from lateral sides by side etching and, because the metal layer is thinner than the post 152, the metal layer is removed to a center side of the post 152 with respect to the side surface of the post 152. After the metal layer is removed to a center side of the post 152 with respect to the side surface of the post 152, the solder layer 155 diffuses via a reflow soldering step and protrudes to the upper side and to the lateral sides in the form of a curved surface (for example, spherically). At that time, the metal layer and the solder layer 155 react and the alloy layer 154 made of the intermetallic compound is formed in the interface between the protective metal layer 153 and the solder layer 155.

The metal layer is removed to the center side of the post 152 with respect to the side surface of the post 152 and thus, when the metal layer and the solder layer 155 react in the reflow soldering step, the alloy layer 154 whose side surface is positioned on the center side of the post 152 with respect to the side surface of the post 152 is formed. The upper surface and the side surface of the alloy layer 154 are covered with the solder layer 155. It is thus possible to inhibit the solder layer 155 covering the side surface of the alloy layer 154 from extending from the side surface in the lateral direction. Note a step of forming the connecting terminal 150 will be described in detail below.

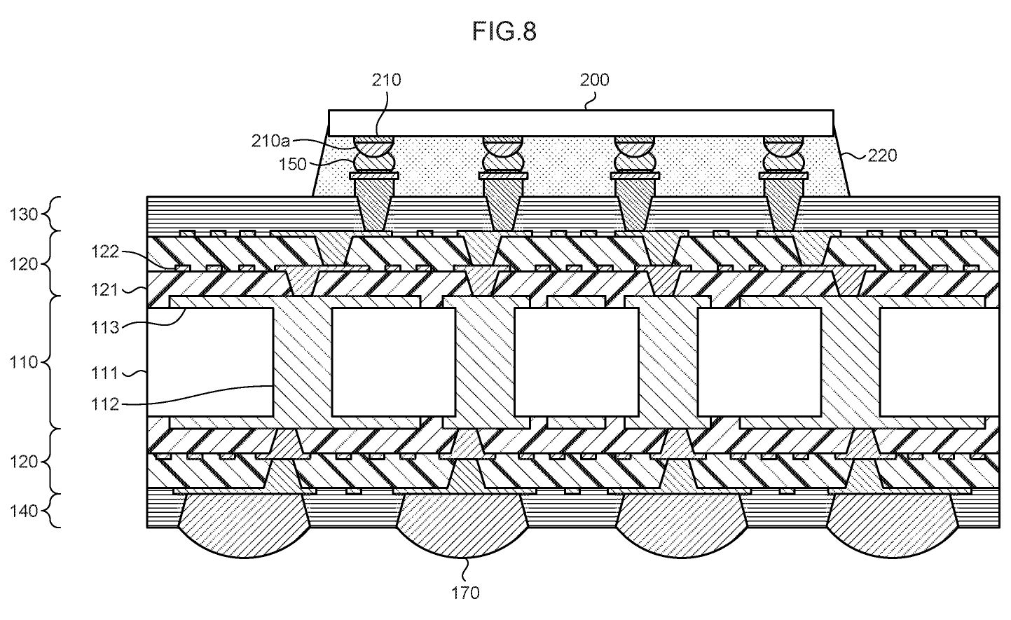

After the connecting terminals 150 are formed on the side of the solder resist layer 130, the external connecting terminals are formed on the side of the solder resist layer 140 (step S105). The semiconductor chip is mounted on the side of the solder resist layer 130 (step S106) and the connecting terminals 150 and the electrodes of the semiconductor chip are connected. Specifically, for example, as illustrated in FIG. 8, the external connecting terminals such as solder balls 170 are formed in the openings 141 of the solder resist layer 140. A semiconductor chip 200 is mounted above the connecting terminals 150 and electrodes 210 of the semiconductor chip 200 are joined to the connecting terminals 150. A bump 210a with which the electrode 210 of the semiconductor chip 200 is provided and the connecting terminal 150 fuse by reflow soldering and are integrated. FIG. 8 is a diagram illustrating a specific example of a semiconductor chip mounting step.

A joint between the electrode 210 and the connecting terminal 150 is sealed with an underfill resin 220 and the semiconductor device in which the semiconductor chip 200 is mounted on the wiring board 100 is achieved. Note that the step of forming the external connecting terminals and the step of mounting the semiconductor chip may be performed in a reversed order. In other words, after the semiconductor chip 200 is mounted on the wiring board 100, the external connecting terminals such as the solder balls 170 may be formed in the openings 141 of the solder resist layer 140.

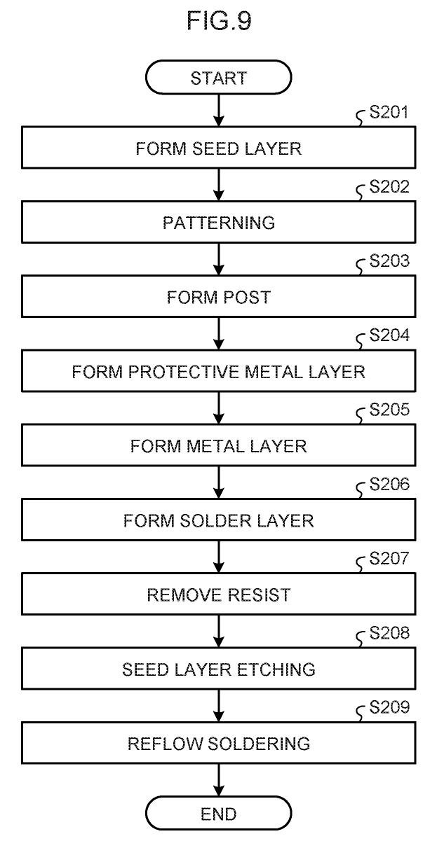

The step of forming the connecting terminals 150 for connecting the semiconductor chip 200 will be described more specifically next with reference to FIG. 9. FIG. 9 is a flowchart illustrating the connecting terminal forming step according to the embodiment.

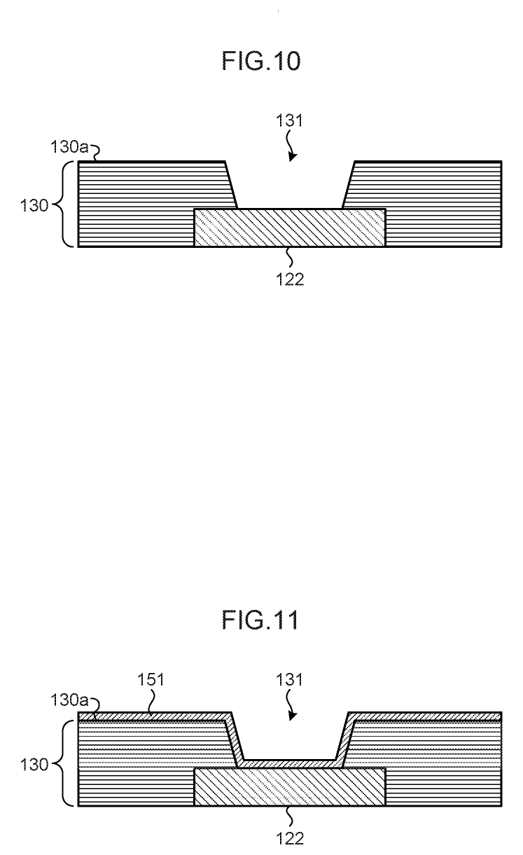

After the multi-layered interconnect structure 120 is layered on the upper surface of the core substrate 110, the interconnect layer 122 of the multi-layered interconnect structure 120 is covered with the solder resist layer 130. In the solder resist layer 130, the openings 131 are formed, for example, as illustrated in FIG. 10. FIG. 10 is a diagram illustrating the opening 131 of the solder resist layer 130. The opening 131 is formed in, for example, a circular shape in the plane view. The interconnect layer 122 is exposed to a bottom of the opening 131.

In this state, the seed layer is formed on the upper surface 130a of the solder resist layer 130 (step S201). In other words, for example, as illustrated in FIG. 11, the seed layer 151 that continuously covers the upper surface 130a of the solder resist layer 130, the inner surface of the opening 131, and the upper surface of the interconnect layer 122 exposed to the bottom part of the opening 131 is formed by electroless copper plating. FIG. 11 is a diagram illustrating formation of a seed layer. The seed layer 151 can have a thickness of, for example, approximately 10 nm to 500 nm.

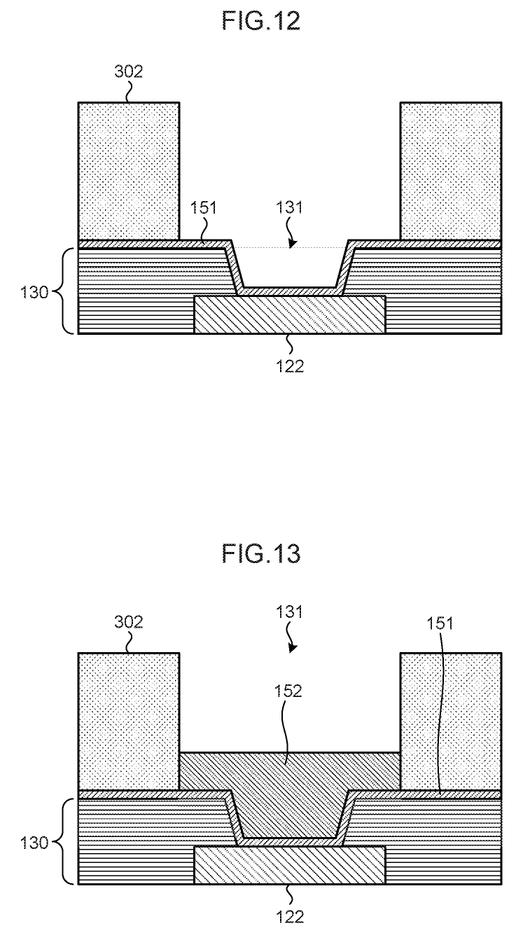

Patterning to form a circuit pattern on a surface of the wiring board 100 is then performed (step S202). Specifically, for example, as illustrated in FIG. 12, after a dry film resist (DFR) 302 is attached to the surface of the wiring board 100, exposure and development on the circuit pattern are performed and the DFR 302 is removed from the interconnect part containing the openings 131. FIG. 12 is a diagram illustrating the patterning.

Power is supplied from the seed layer 151 and electrolytic copper plating is performed and accordingly the post 152 is formed on the upper surface of the seed layer 151 (step S203). Specifically, for example, by performing electrolytic copper plating using, for example, a copper sulfate plating solution, copper (Cu) is deposited

on a part where the DFR 302 is not formed and, for example, as illustrated in FIG. 13, the post 152 is formed on the upper surface of the seed layer 151. At that time, the opening 131 is filled by electrolytic plating. FIG. 13 is a diagram illustrating formation of the post. The post 152 has a thickness (in other words, a thickness of only an upper part with respect to the upper surface of the seed layer 151 excluding the part in the opening 131) of, for example, approximately 2 μm to 50 μm.

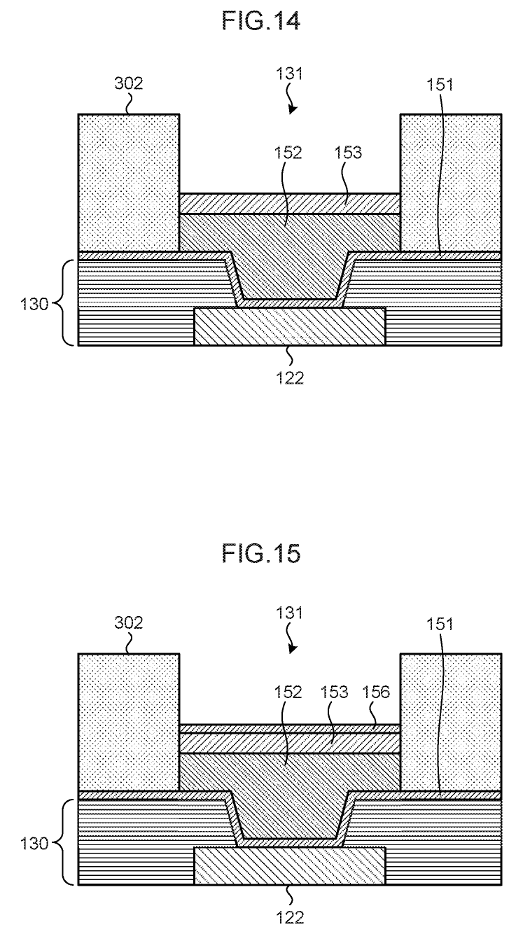

After the post 152 is formed, power is supplied from the seed layer 151 and electrolytic nickel plating is performed and accordingly, for example, as illustrated in FIG. 14, the protective metal layer 153 is formed on the upper surface of the post 152 (step S204). FIG. 14 is a diagram illustrating formation of the protective metal layer. Because of formation of the protective metal layer 153 on the upper surface of the post 152, the protective metal layer 153 that is a metal layer different from the post 152 is interposed between the post 152 and the solder layer 155. Interposition of the protective metal layer 153 makes it possible to inhibit copper (Cu) in the post 152 from diffusing to tin (Sn) in the solder layer 155. The protective metal layer 153 can have a thickness of, for example, approximately 0.01 μm to 3 μm.

After the protective metal layer 153 is formed, power is supplied from the seed layer 151 and electrolytic copper plating is performed and accordingly, for example, as illustrated in FIG. 15, a metal layer 156 is formed on the upper surface of the protective metal layer 153 (step S205). FIG. 15 is a diagram illustrating formation of the metal layer. The metal layer 156 can have a thickness of, for example, approximately 1 μm to 4 μm that is smaller than the thickness of the post 152 (that is, the thickness of only the upper part with respect to the upper surface of the seed layer 151 excluding the part in the opening 131). When the metal layer 156 has a thickness smaller than 1 μm, the alloy layer 154 in a sufficient thickness is not formed when the reflow soldering step to be described below is executed. When the metal layer 156 has a thickness larger than 4 μm, copper (Cu) in the metal layer 156 remains in the alloy layer 154 that is formed when the reflow soldering step is executed.

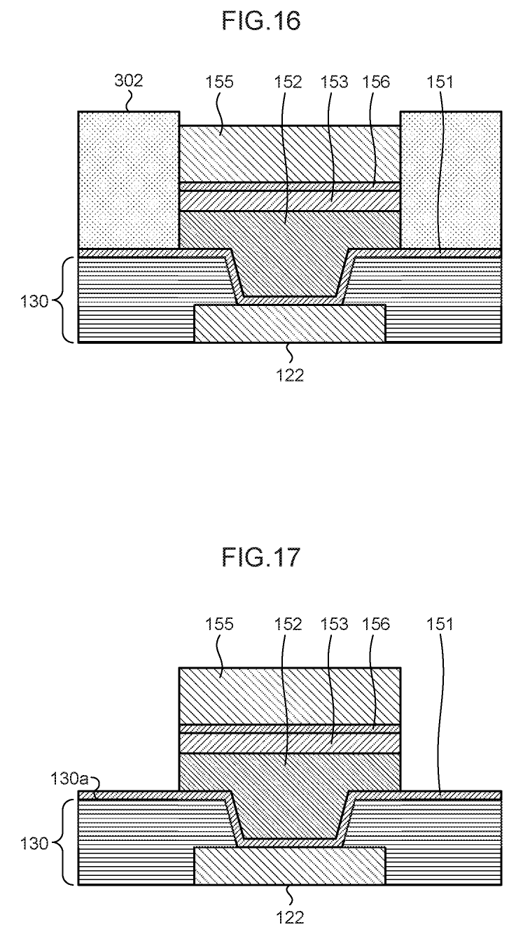

After the metal layer 156 is formed, power is supplied from the seed layer 151 and electrolytic tin plating is performed and accordingly, for example, as illustrated in FIG. 16, the solder layer 155 is formed on the upper surface of the protective metal layer 153 via the metal layer 156 (step S206). FIG. 16 is a diagram illustrating formation of the solder layer.

After the solder layer 155 is formed, the DFR 302 is removed (step S207). For removal of the DFR 302, for example, caustic soda or an amine alkaline stripping solution is used. Because of removal of the DFR 302, for example, as illustrated in FIG. 17, the seed layer 151, the post 152, the protective metal layer 153, the metal layer 156, and the solder layer 155 are layered in the position of the opening 131 and are in a state of projecting from the upper surface 130a of the solder resist layer 130. FIG. 17 is a a diagram illustrating removal of the resist. At this stage, because the seed layer 151 remains over the surface and the post 152 is short-circuited with other posts, it is necessary to remove an unnecessary part of the seed layer 151 not overlapping the post 152.

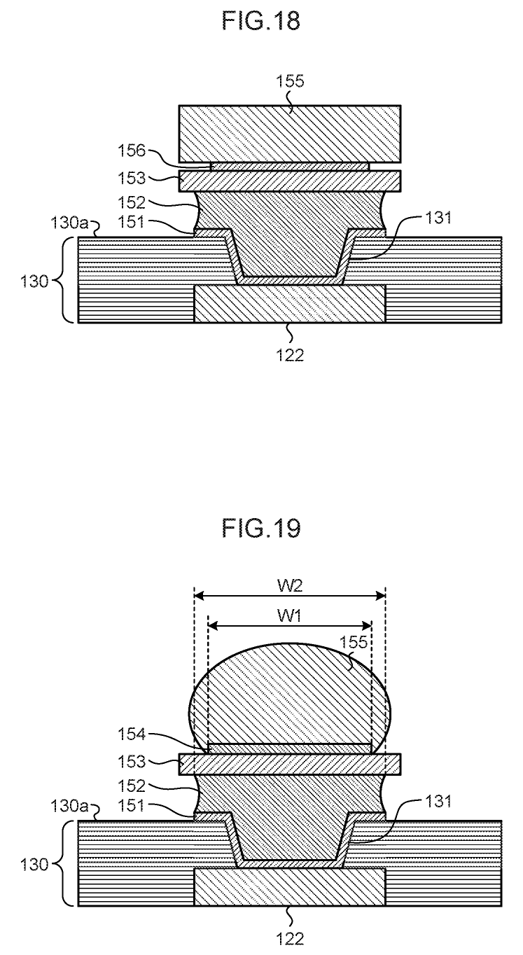

Thus, etching on the seed layer 151 is performed using the post 152 as a mask (step S208). Specifically, the seed layer 151 formed on the upper surface 130a of the solder resist layer 130 is immersed into, for example, an etching solution that selectively dissolves copper and, for example, as illustrated in FIG. 18, the unnecessary part of the seed layer 151 not overlapping the post 152 is removed. FIG. 18 is a diagram illustrating the seed layer etching.

In etching on the seed layer 151, the unnecessary part of the seed layer 151 is dissolved and, at the same time, side etching progresses and the post 152 and the metal layer 156 are dissolved from the lateral sides. Once the post 152 and the metal layer 156 are dissolved from the lateral sides by side etching, the side surface of the post 152 and the side surface of the metal layer 156 curve in a form of a concave curved surface. The metal layer 156 is thinner than the post 152 and therefore the progress in side etching on the metal layer 156 is faster than the progress in side etching on the post 152. In other words, the amount of side etching on the metal layer 156 is larger than the amount of side etching on the post 152. As a result, the metal layer 156 is removed to the center side of the post 152 with respect to the side surface of the post 152 and the side surface of the metal layer 156 recedes to the center side of the post 152 with respect to the side surface of the post 152. In other words, the width of the metal layer 156 is smaller than the width of the post 152 (the maximum width of the post 152 at the periphery of the side surface in the form of the concave curved surface).

Because of etching that removes the seed layer 151, the seed layer 151, the post 152, the protective metal layer 153, the metal layer 156, and the solder layer 155 are layered in the position of the opening 131 and a conductor projecting from the upper surface 130a of the solder resist layer 130 is formed.

Thereafter, reflow soldering at a reflow soldering temperature at which the solder layer 155 fuses is executed (step S209). In other words, the solder layer 155 is fused under reflow soldering conditions including the reflow soldering temperature and a reflow soldering time that are determined previously, thereafter, is cooled, and accordingly is solidified. Accordingly, the solder layer 155 (solder bump) that is hemisphere is obtained.

Accordingly, for example, as illustrated in FIG. 19, the upper surface of the solder layer 155 protrudes in the form of a curved surface (for example, spherically) and the connecting terminal 150 is formed. FIG. 19 is a diagram illustrating reflow soldering. In reflow soldering, the metal layer 156 and the solder layer 155 react and the alloy layer 154 made of the intermetallic compound is formed in the interface between the protective metal layer 153 and the solder layer 155. For example, copper (Cu) diffused from the metal layer 156 reacts with tin (Sn) of the solder layer 155 and nickel (Ni) of the protective metal layer 153 and the alloy layer 154 made of (Cu,Ni)₆Sn₅ that is the intermetallic compound is formed. The reflow soldering conditions applied to reflow soldering are set such that the alloy layer 154 made of the intermetallic compound is formed in the interface between the protective metal layer 153 and the solder layer 155. For example, it is possible to execute reflow soldering under reflow soldering conditions of a reflow temperature of approximately 230°C to 280°C and a reflow soldering time of 10 to 200 seconds.

Here, because the metal layer 156 is removed to the center side of the post 152 with respect to the side surface of the post 152, the metal layer 156 and the solder layer 155 react and accordingly the alloy layer 154 whose side surface is positioned on the center side of the post 152 with respect to the side surface of the post 152 formed. In other words, a width W1 of the alloy layer 154 is smaller than a width W2 of the post 152 (the maximum width of the post 152 at the periphery of the side surface in the form of the concave curved surface). Then the solder layer 155 that covers the upper surface and the side surface of the alloy layer 154 is formed. Thus, it is possible to inhibit the solder layer 155 covering the side surface of the alloy layer 154 from extending in the lateral direction from the side surface of the alloy layer 154. As a result, it is possible to inhibit occurrence of short-circuiting between the connecting terminals 150 that are adjacent to each other.

Note that, the post 152, the protective metal layer 153, the alloy layer 154, and the solder layer 155 may be circular in the plane view in the connecting terminal 150. In this case, a magnitude relation in diameter among the post 152, the protective metal layer 153, the alloy layer 154, and the solder layer 155 may correspond to a magnitude relation in width among the post 152, the protective metal layer 153, the alloy layer 154, and the solder layer 155.

### Modification

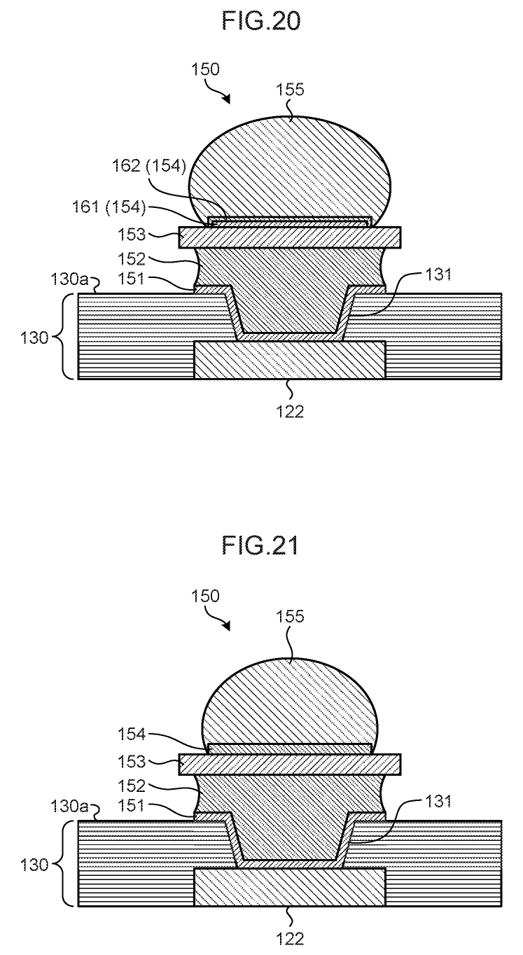

Various types of modifications of the embodiment will be described next with reference to FIGS. 20 to 26. Note that, in the modifications presented below, the same parts as those of the embodiment are denoted with the same reference numerals and thus redundant description thereof is sometimes omitted.

FIG. 20 is a diagram illustrating a structure of the connecting terminal 150 according to Modification 1 of the embodiment. In the above-described embodiment, the case where the whole alloy layer 154 is a layer made of the intermetallic compound is exemplified; however, part of the alloy layer 154 may be made of the intermetallic compound and copper (Cu) forming the metal layer 156 may remain in other part of the alloy layer 154. In other words, the alloy layer 154 may be a double-layer structure of copper (Cu) forming the metal layer 156 and the intermetallic compound. For example, as illustrated in FIG. 20, the alloy layer 154 may include a core layer 161 made of copper (Cu) forming the metal layer 156 and an interface layer 162 made of an intermetallic compound containing at least copper (Cu) forming the core layer 161 and tin (Sn) forming the solder layer 155. The core layer 161 is positioned on the upper surface of the protective metal layer 153 and the interface layer 162 is positioned in the interface between the core layer 161 and the solder layer 155.

The alloy layer 154 that is the double-layer structure can be formed in a way that a reflow time is shorter than a given time. The alloy layer 154 that is the double-layer structure can be also formed in a way that the metal layer 156 formed on the upper surface of the protective metal layer 153 has a thickness of, for example, 4 μm or larger.

In Modification 1, because the alloy layer 154 is a double-layer structure of copper (Cu) and the intermetallic compound, it is possible to further inhibit of the solder layer 155 from diffusing to Ni of the protective metal layer 153 and inhibit a progress in reaction of Ni of the protective metal layer 153. As a result, because it is possible to further inhibit depletion of Ni in the protective metal layer 153, it is possible to further inhibit rupture of the connecting terminal 150 in the position of the protective metal layer 153.

FIG. 21 is a diagram illustrating a structure of the connecting terminal 150 according to Modification 2 of the embodiment. The wiring board 100 according to Modification 2 is different in the configuration of the solder layer 155 of the connecting terminal 150.

In other words, as illustrated in FIG. 21, the solder layer 155 may have a width smaller than that of the post 152. The width of the solder layer 155 is adjustable by reducing the thickness of the solder layer 155 formed on the upper surface of the protective metal layer 153 to one smaller than a given thickness.

In Modification 2, because the solder layer 155 has the width smaller than the width of the post 152, it is possible to further inhibit occurrence of short-circuiting between the connecting terminals 150 that are adjacent to each other.

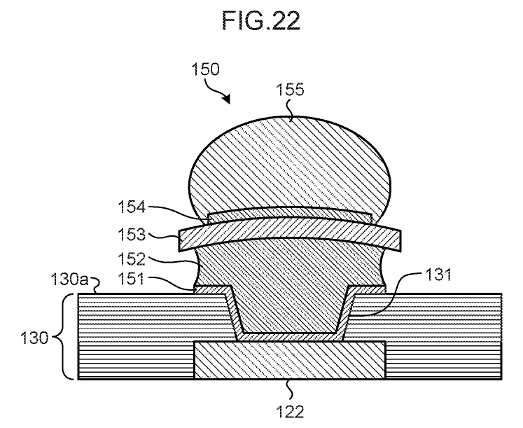

FIG. 22 is a diagram illustrating a structure of the connecting terminal 150 according to Modification 3 of the embodiment. In the above-described embodiment, the case where the upper surface of the post 152, the upper surface of the protective metal layer 153, and the upper surface of the alloy layer 154 are flat surfaces is exemplified; however, the shapes of the post 152, the protective metal layer 153, and the alloy layer 154 are not limited this. For example, as illustrated in FIG. 22, the upper surface of the post 152 may protrude to an upper side in the form of a curved surface (for example, spherically).

The upper surface of the protective metal layer 153 and the upper surface of the alloy layer 154 may curve in the form of a curved surface (for example, spherically) corresponding to the upper surface of the post 152.

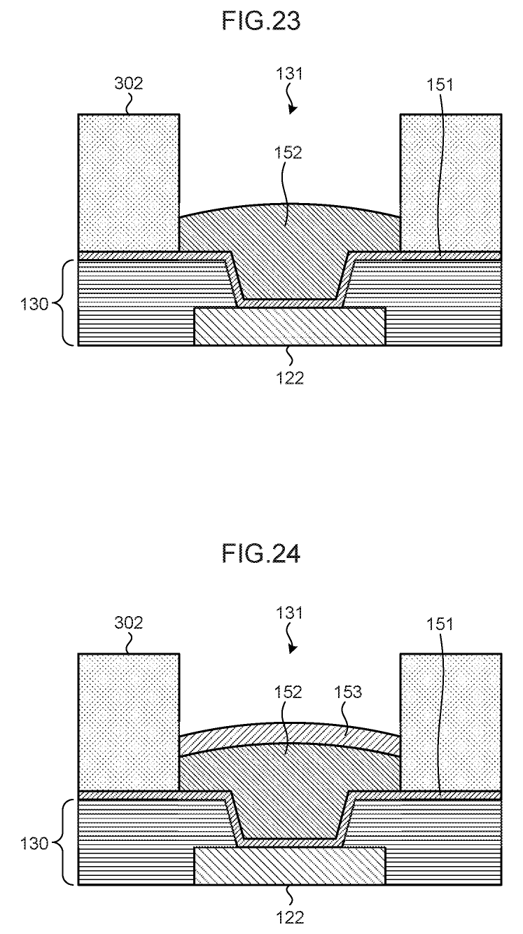

In the case where the connecting terminal 150 illustrated in FIG. 22 is formed, after the DFR 302 is removed from the interconnect part including the opening 131 by patterning, electrolytic copper plating is performed at a given current density and accordingly the post 152 is formed on the upper surface of the seed layer 151. In other words, electrolytic copper plating is performed at a current density larger than a current density by which the upper surface of the post 152 is flat and accordingly, for example, as illustrated in FIG. 23, the upper surface of the post 152 formed on the upper surface of the seed layer 151 protrudes to the upper side in the form of a curved surface (for example, spherically). FIG. 23 is a diagram illustrating formation of the post.

After the post 152 is formed, electrolytic nickel plating is performed and accordingly the protective metal layer 153 is formed on the upper surface of the post 152. To form the protective metal layer 153, plating in a uniform thickness is performed along the upper surface of the post 152. Thus, for example, as illustrated in FIG. 24, the upper surface of the protective metal layer 153

formed on the upper surface of the post 152 curves in the form of a curved surface (for example, spherically) corresponding to the upper surface of the post 152. FIG. 24 is a diagram illustrating formation of the protective metal layer.

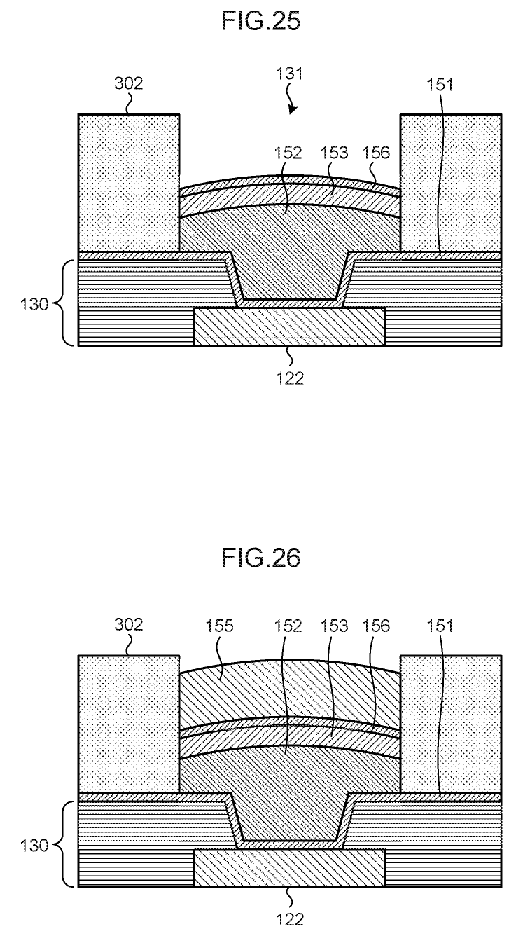

After the protective metal layer 153 is formed, electrolytic copper plating is performed and accordingly the metal layer 156 is formed on the upper surface of the protective metal layer 153. To form the metal layer 156, plating in a uniform thickness is performed along the upper surface of the protective metal layer 153. Thus, for example, as illustrated in FIG. 25, the upper surface of the metal layer 156 formed on the upper surface of the protective metal layer 153 curves in the form of a curved surface (for example, spherically) corresponding to the upper surface of the post 152 and the upper surface of the protective metal layer 153. FIG. 25 is a diagram illustrating formation of the metal layer.

After the metal layer 156 is formed, electrolytic tin plating is performed and accordingly the solder layer 155 is formed on the upper surface of the protective metal layer 153 via the metal layer 156. To form the solder layer 155, plating in a uniform thickness is performed along the upper surface of the protective metal layer 153 via the metal layer 156. Thus, as illustrated in FIG. 26, the upper surface of the solder layer 155 formed on the upper surface of the protective metal layer 153 via the metal layer 156 curves in the form of a curved surface (for example, spherically) corresponding to the upper surface of the post 152, the upper surface of the protective metal layer 153, and the upper surface of the metal layer 156. FIG. 26 is a diagram illustrating formation of the solder layer.

Thereafter, as in the embodiment, removal of the DFR 302, etching on the seed layer 151, and reflow soldering are performed and accordingly the connecting terminal 150 illustrated in FIG. 22 is formed.

As described above, in Modification 3, the upper surface of the post 152 protrudes to the upper side in the form of a curved surface (for example, spherically) and the upper surface of the protective metal layer 153 and the upper surface of the alloy layer 154 curve in the form of a curved surface (for example, spherically) corresponding to the upper surface of the post 152. Accordingly, compared to the case where the upper surface of the post 152, the upper surface of the protective metal layer 153, and the upper surface of the alloy layer 154 are flat surfaces, the area of the bonding surface between the post 152 and the protective metal layer 153 and the interface (that is, the bonding surface) between the protective metal layer 153 and the solder layer 155 increases. As a result, a bonding strength between the post 152 and the protective metal layer 153 and a bonding strength between the protective metal layer 153 and the solder layer 155 can be increased.

As described above, a wiring board according to an embodiment (the wiring board 100 in an example) includes an insulating layer (the solder resist layer 130 in an example), and a connecting terminal (the connecting terminal 150 in an example) that is formed on an upper surface (the upper surface 130a in an example) of the insulating layer. The connecting terminal includes a seed layer (the seed layer 151 in an example), a metal post (the post 152 in an example), a protective metal layer (the protective metal layer 153 in an example), a solder layer (the solder layer 155 in an example), and an alloy layer (the alloy layer 154 in an example). The seed layer is layered on the upper surface of the insulating layer. The post is layered on an upper surface of the seed layer. The protective metal layer is layered on an upper surface of the post. The solder layer is formed on an upper surface of the protective metal layer. The alloy layer is formed in an interface between the protective metal layer and the solder layer and is at least partly made of an intermetallic compound. The solder layer covers an upper surface and a side surface of the alloy layer. A side surface of the alloy layer is positioned on a center side of the post with respect to a side surface of the post. Accordingly, it is possible to inhibit occurrence of short-circuiting between connecting terminals adjacent to each other.

According to a mode of a wiring board disclosed herein, an effect that it is possible to inhibit occurrence of short-circuiting between adjacent connecting terminals is achieved.

(Note) (1) A method of manufacturing a wiring board comprising:

a seed layer layering step of layering a seed layer on an upper surface of an insulating layer;

a post forming step of forming a post of a metal on an upper surface of the seed layer;

a protective metal layer layering step of layering a protective metal layer on an upper surface of the post;

a metal layer layering step of layering a metal layer on an upper surface of the protective metal layer;

a solder layer layering step of layering a solder layer on the upper surface of the protective metal layer via the metal layer;

a removing step of removing a part of the seed layer not overlapping the post by etching; and

a reflow soldering step of, by fusing the solder layer to cause the metal layer and the solder layer to react, forming an alloy layer at least partly made of an intermetallic compound in an interface between the protective metal layer and the solder layer,

wherein the removing step includes dissolving the post and the metal layer from a lateral side simultaneously with removal of the seed layer and removing the metal layer to a center side of the post with respect to a side surface of the post, and

the reflow step includes forming the alloy layer whose side surface is positioned on a center side of the post with respect to a side surface of the post by causing the metal layer after the removing step and the solder layer to react and forming the solder layer covering an upper surface and a side surface of the alloy layer.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
an insulating layer; and
a connecting terminal that is formed on an upper surface of the insulating layer,
wherein the connecting terminal includes
a seed layer that is layered on the upper surface of the insulating layer;
a post of a metal that is layered on an upper surface of the seed layer;
a protective metal layer that is layered on an upper surface of the post;
a solder layer that is formed on an upper surface of the protective metal layer; and
an alloy layer that is formed in an interface between the protective metal layer and the solder layer and that is at least partly made of an intermetallic compound,
the solder layer covers an upper surface and a side surface of the alloy layer, and
the side surface of the alloy layer is positioned on a center side of the post with respect to a side surface of the post.

2. The wiring board according to claim 1, wherein the alloy layer has a width smaller than a width of the post.

3. The wiring board according to claim 1, wherein the protective metal layer is a layer of a metal different from the post, and
the alloy layer is made of the intermetallic compound containing at least a metal different from the protective metal layer and a metal that forms the solder layer.

4. The wiring board according to claim 1, wherein the protective metal layer is a layer of a metal different from the post, and
the alloy layer includes
a core layer that is positioned on the upper surface of the protective metal layer and that is made of a metal different from the protective metal layer; and
an interface layer that is positioned in an interface between the core layer and the solder layer and that is made of the intermetallic compound containing at least the metal forming the core layer and a metal that forms the solder layer.

5. The wiring board according to claim 1, wherein a side surface of the protective metal layer is positioned on an outer side with respect to the side surface of the post,
the side surface of the alloy layer is positioned on a center side of the post with respect to the side surface of the protective metal layer, and
the solder layer extends from the side surface of the alloy layer to a position not reaching the side surface of the protective metal layer and exposes an area not overlapping the solder layer in a plane view in the upper surface of the protective metal layer.

6. The wiring board according to claim 1, wherein the solder layer has a width smaller than a width of the protective metal layer.

7. The wiring board according to claim 1, wherein the solder layer has a width smaller than a width of the post.

8. The wiring board according to claim 1, wherein the solder layer has a width larger than a width of the post.

9. The wiring board according to claim 1, wherein the solder is hemispherical.

10. The wiring board according to claim 1, wherein the upper surface of the post protrudes in a form of a curved surface, and
the upper surface of the protective metal layer and the upper surface of the alloy layer curve in a form of a curved surface corresponding to the upper surface of the post.
